(19) United States
(12) Patent Application Publication
(10) Pub. No.: US 2009/0108412 A1
(43) Pub. Date: Apr. 30, 2009

(54) SEMICONDUCTOR SUBSTRATE AND METHOD FOR MANUFACTURING A SEMICONDUCTOR SUBSTRATE

(76) Inventors: Hiroshi ITOKAWA, Yokohama-shi (JP); Ichiro MIZUSHIMA, Yokohama-shi (JP); Akiko NOMACHI, Yokohama-shi (JP); Yoshitaka TSUNASHIMA, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/258,650

(22) Filed: Oct. 27, 2008

(30) Foreign Application Priority Data
Oct. 29, 2007 (JP) 2007-280564

(51) Int. Cl. H01L 29/04; H01L 21/18; H01L 21/30

(52) U.S. Cl. 257/629; 438/455; 438/527; 257/E29.003; 257/E21.085; 257/E21.211

(57) ABSTRACT

A semiconductor substrate includes: a silicon support substrate with a first crystal orientation; a silicon functional substrate which is formed on the silicon support substrate and which has a first crystalline region with a crystal orientation different from the first crystal orientation of the silicon support substrate and a second crystalline region with a crystal orientation equal to the first crystal orientation of the silicon support substrate; and a defect creation-preventing region formed at an interface between the first crystalline region and the second crystalline region of the silicon functional substrate so as to be at least elongated to a main surface of the silicon support substrate.

### CROSS-REFERENCE TO RELATED APPLICATIONS

This application is based upon and claims the benefit of priority from the prior Japanese Patent Application No. 2007-280564 filed on Oct. 29, 2007; the entire contents which are incorporated herein by reference.

### BACKGROUND OF THE INVENTION

1. Field of the Invention

The present invention relates to a HOT (Hybrid Orientation Technique) semiconductor substrate which has different orientations therein and a method for manufacturing the semiconductor substrate.

2. Description of the Related Art

Recently, in order to maximize the mobility of carrier in a transistor and thus, enhance the performance of the transistor, a HOT (Hybrid Orientation Technique) substrate which has different crystal orientations for the n-type channel (electron) region and the p-type channel (hole) region comes under review.

Normally, the HOT substrate would be made as follows: First of all, a DSB (Direct Silicon Bond) substrate made by laminating two substrates with respective different crystal orientations (for example, one is a functional substrate to be used for carrier mobility in a transistor or the like and the other is a support substrate for supporting the functional substrate) is prepared, and impurity doping is carried out for the functional substrate via an insulating film as a mask so as to render the functional substrate amorphous. Then, thermal treatment is carried out for the amorphous functional substrate so that the crystal orientation of the functional substrate can be equal to the crystal orientation of the support substrate through the recrystallization of the functional substrate. In this case, the functional substrate has a first crystalline region with the inherent crystal orientation different from the crystal orientation of the support substrate not subject to the impurity doping via the mask and a second crystalline region with the same crystal orientation as the one of the support substrate through the recrystallization (Reference 1).

[Reference 1] H. Yin et al., Symp. on VLSI Technology Dig. (2007) 222

In the formation process of the substrate as described above, however, the functional substrate results in having the first crystalline region inherent thereto and the amorphous region made by the impurity doping such that the first crystalline region is directly adjacent to the amorphous region. In the recrystallization of the amorphous region, therefore, a large amount of defects may be created around the interface between the first crystalline region and the amorphous region because different kinds of material of the crystalline material (first crystalline region) and the amorphous material (amorphous region) are directly joined with one another. As a result, the resultant functional substrate may have crystal defect at high density therein so that the carrier mobility in the functional substrate may be deteriorated.

In this point of view, it may be that the HOT semiconductor can not sufficiently exhibit the inherent function such as the enhancement of carrier mobility as designed initially due to the crystal defect created therein.

### BRIEF SUMMARY OF THE INVENTION

An aspect of the present invention relates to a semiconductor substrate, including: a silicon support substrate with a first crystal orientation; a silicon functional substrate which is formed on the silicon support substrate and which has a first crystalline region with a crystal orientation different from the first crystal orientation of the silicon support substrate and a second crystalline region with a crystal orientation equal to the first crystal orientation of the silicon support substrate; and a defect creation-preventing region formed at an interface between the first crystalline region and the second crystalline region of the silicon functional substrate so as to be at least elongated to a main surface of the silicon support substrate.

Another aspect of the present invention relates to a method for manufacturing a semiconductor substrate, including: laminating, on a silicon support substrate with a first crystal orientation, a silicon functional substrate with a second crystal orientation different from the first crystal orientation; forming an insulating film so as to cover a portion of a main surface of the silicon functional substrate; conducting first ion implantation for the silicon functional substrate so as to render amorphous a portion not covered with the insulating film of the silicon functional substrate to form an amorphous silicon layer in the silicon functional substrate; forming an additional insulating film so as to cover the amorphous silicon layer and position an opening at an interface between the amorphous silicon layer and an adjacent non-amorphous silicon layer; conducting second ion implantation via the opening to form an ion implantation layer as a defect creation-preventing layer so as to be at least elongated to a main surface of the silicon support substrate; and conducting thermal treatment for the silicon support substrate and the silicon functional substrate to recrystallize the amorphous silicon layer.

Still another aspect of the present invention relates to a method for manufacturing a semiconductor substrate, including: laminating, on a silicon support substrate with a first crystal orientation, a silicon functional substrate with a second crystal orientation different from the first crystal orientation; forming an insulating film so as to have an opening almost at a center of a main surface of the silicon functional substrate; conducting first ion implantation via the opening to form an ion implantation layer as a defect creation-preventing layer so as to be at least elongated to a main surface of the silicon support substrate; removing a portion of the insulating film and conducting second ion implantation for the silicon functional substrate so as to render amorphous a portion not covered with the insulating film of the silicon functional substrate to form an amorphous silicon layer in the silicon functional substrate; and conducting thermal treatment for the silicon support substrate and the silicon functional substrate to recrystallize the amorphous silicon layer.

A further aspect of the present invention relates to a method for manufacturing a semiconductor substrate, including: forming a phase transition-preventing layer on a silicon support substrate with a first crystal orientation; laminating, on the silicon support substrate, a silicon functional substrate with a second crystal orientation different from the first crystal orientation via the phase transition-preventing layer; forming an insulating film so as to cover a portion of a main surface of the silicon functional substrate; conducting first ion implantation for the silicon functional substrate so as to render amorphous a portion not covered with the insulating film of the silicon functional substrate to form an amorphous silicon layer in the silicon functional substrate; forming an additional insulating film so as to cover the amorphous silicon layer and position an opening at an interface between the amorphous silicon layer and an adjacent non-amorphous silicon layer; conducting second ion implantation via the opening to form an ion implantation layer as a defect creation-preventing layer so as to be at least elongated to a main surface of the silicon support substrate; and conducting thermal treatment for the silicon support substrate and the silicon functional substrate to recrystallize the amorphous silicon layer.

Another aspect of the present invention relates to a method for manufacturing a semiconductor substrate, including: forming a phase transition-preventing layer on a silicon support substrate with a first crystal orientation; laminating, on the silicon support substrate, a silicon functional substrate with a second crystal orientation different from the first crystal orientation via the phase transition-preventing layer; forming an insulating film so as to form an opening almost at a center of a main surface of the silicon functional substrate; conducting first ion implantation via the opening to form an ion implantation layer as a defect creation-preventing layer so as to be at least elongated to a main surface of the silicon support substrate; removing a portion of the insulating film and conducting second ion implantation for the silicon functional substrate so as to render amorphous a portion not covered with the insulating film of the silicon functional substrate to form an amorphous silicon layer in the silicon functional substrate; and conducting thermal treatment for the silicon support substrate and the silicon functional substrate to recrystallize the amorphous silicon layer.

### BRIEF DESCRIPTION OF THE DRAWINGS

FIG. 1 is a cross sectional view schematically showing the structure of a HOT semiconductor substrate according to a first embodiment.

FIG. 2 is a cross sectional view schematically showing the structure of a conventional HOT semiconductor substrate.

FIG. 3 is a cross sectional view schematically showing the structure of a HOT semiconductor substrate according to a second embodiment.

FIG. 4 is a cross sectional view schematically showing a step in a method for manufacturing a semiconductor substrate according to a first embodiment and a second embodiment.

FIG. 5 is a cross sectional view schematically showing a step in the manufacturing method of the first embodiment.

FIG. 6 is a cross sectional view schematically showing a step in the manufacturing method of the first embodiment.

FIG. 7 is a cross sectional view schematically showing a step in the manufacturing method of the second embodiment.

FIG. 8 is a cross sectional view schematically showing a step in the manufacturing method of the second embodiment.

FIG. 9 is a cross sectional view schematically showing a step in a method for manufacturing a semiconductor substrate according to a third embodiment and a fourth embodiment.

FIG. 10 is a cross sectional view schematically showing a step in the manufacturing method of the third embodiment.

FIG. 11 is a cross sectional view schematically showing a step in the manufacturing method of the third embodiment.

FIG. 12 is a cross sectional view schematically showing a step in the manufacturing method of the third embodiment.

FIG. 13 is a cross sectional view schematically showing a step in the manufacturing method of the fourth embodiment.

FIG. 14 is a cross sectional view schematically showing a step in the manufacturing method of the fourth embodiment.

### DETAILED DESCRIPTION OF THE INVENTION

Then, some embodiments will be described with reference to the drawings.

### (Semiconductor Substrate)

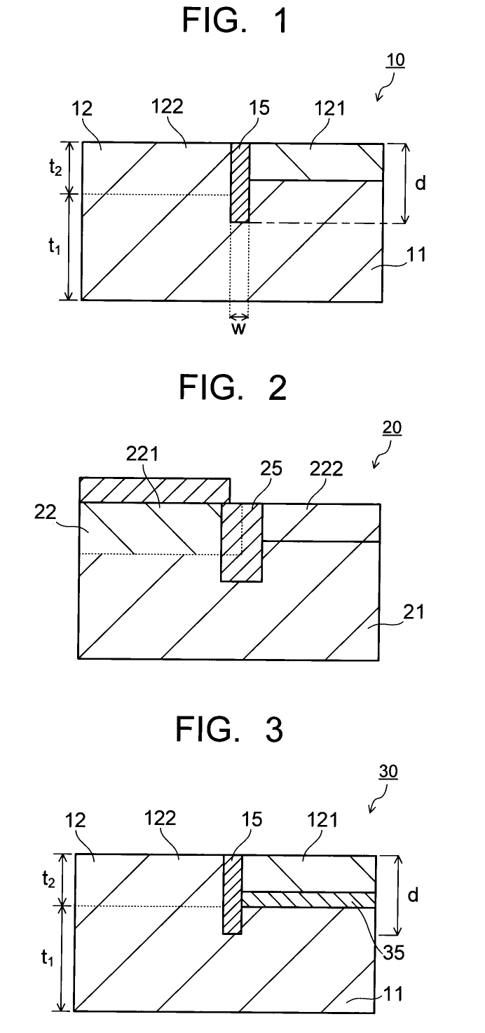

FIG. 1 is a cross sectional view schematically showing the structure of a HOT semiconductor substrate according to a first embodiment. FIG. 2 is across sectional view schematically showing the structure of a conventional HOT semiconductor substrate. In FIGS. 1 and 2, only the main portion of the semiconductor substrate is enlargedly shown. In a practical semiconductor substrate, the structure as shown in FIG. 1 or FIG. 2 is defined as one unit so that a plurality of units are formed and arranged.

As shown in FIG. 1, the HOT semiconductor substrate 10 in this embodiment includes a support substrate 11 and a functional substrate 12 formed so as to be directly laminated on the support substrate 11. The support substrate 11 and functional substrate 12 are made by corresponding silicon substrates with respective different crystal orientations. For Example, the functional substrate 12 is made of (110) Si substrate and the support substrate 11 is made of (100) Si substrate. However, the support substrate 11 and functional substrate 12 have only to be made by corresponding silicon substrates with respective different crystal orientations as described above so that the support substrate 11 and the functional substrate 12 may be appropriately made of (100) Si substrate, (110) Si substrate and (111) Si substrate so as to satisfy the above-mentioned requirement.

Moreover, the functional substrate 12 includes a first crystalline region 121 and a second crystalline region 122. The first crystalline region 121 is separated from the second crystalline region 122 by a defect creation-preventing region 15 formed so as to be elongated into the support substrate 11. The first crystalline region 121 inherits the crystal orientation depending on the manufacturing method to be described in detail hereinafter so that the crystal orientation of the first crystalline region 121 becomes equal to the crystal orientation of the functional substrate 12. The second crystalline region 122 has the same crystal orientation as the one of the support substrate 11 depending on the manufacturing method to be described in detail hereinafter. Therefore, the crystal orientation of the first crystalline region 121 is different from the crystal orientation of the second crystalline region 122.

In this way, the first crystalline region 121 and the second crystalline region 122 are made of the respective different kinds of materials so that in the recrystallization process, a large amount of defects are created around the interface between the first crystalline region 121 and the second crystalline region 122. In the semiconductor substrate 10 in this embodiment, however, since the defect creation-preventing region 15 is formed at the interface between the first crystalline region 121 and the second crystalline region 122, the first crystalline region 121 is not directly joined with the second crystalline region 122 during and after the formation of the first crystalline region 121 and the second crystalline region 122. Therefore, the creation of crystalline defect around the interface between the first crystalline region 121 and the second crystalline region 122 can be prevented.

As a result, the amount of crystalline defect in the functional substrate 12 can be reduced so that the inherent function/effect such as carrier mobility of the functional substrate 12 cannot be deteriorated due to the crystalline defect. For example, the first crystalline region 121 can be employed as the p-type channel (the move of hole) and the second crystalline region 122 can be employed as the n-type channel (the move of electron).

As shown in FIG. 1, in this embodiment, the depth “d” of the defect creation-preventing region 15 is set larger than the thickness “t₂” of the functional substrate 12 so that the defect creation-preventing region 15 is elongated into the support substrate 11. However, the depth “d” of the defect creation-preventing region 15 has only to be set equal to the thickness “t₂” of the functional substrate 12 such that the defect creation-preventing region 15 penetrates through the functional substrate 12 and separates the first crystalline region 121 and the second crystalline region 122 of the functional substrate 12.

The defect creation-preventing region 15 may be formed as an ion-implanted layer made by implanting at least one selected from the group consisting of carbon, nitrogen and oxygen into the functional substrate 12.

In the conventional HOT semiconductor substrate 20 shown in FIG. 2, in contrast, a functional substrate 22 is directly laminated on a support substrate 21. In this case, the crystal orientation of the functional substrate 22 is different from the crystal orientation of the support substrate 21. In the functional substrate 22, a first crystalline region 221 with the crystal orientation inherent to the functional substrate 22 is adjacent to a second crystalline region 222 with the crystal orientation equal to the one of the support substrate 21. In this case, even though the support substrate 21 and the functional substrate 22 are made of the same Si substrate as one another, a large amount of defect 25 are created around the interface between the first crystalline region 221 and the second crystalline region 222 due to the respective different crystal orientations of the first crystalline region 221 and the second crystalline region 222 and dependent on the recrystallizing process in the manufacturing method to be described in detail hereinafter.

As a result, the amount of crystalline defect in the functional substrate 22 is increased so that the inherent function/effect such as the enhancement of carrier mobility of the functional substrate 22 may be deteriorated.

Moreover, in the case that a semiconductor device is made from the semiconductor substrate 20, since an additional processing for the element separation is required for the region containing the defect 25 so as not to contain a large amount of defect 25 in the element region of the functional substrate 22, the manufacturing process of the semiconductor device becomes complicated in comparison with the use of the semiconductor substrate 10.

FIG. 3 is a cross sectional view schematically showing the structure of a HOT semiconductor substrate according to a second embodiment. As shown in FIG. 3, a HOT semiconductor substrate 30 in this embodiment is configured as the HOT semiconductor substrate 10 shown in FIG. 1 except that a phase transition-preventing layer 35 is formed between the support substrate 11 and the functional substrate 12, concretely, the support substrate 11 and the first crystalline region 121 of the functional substrate 12. In this embodiment, therefore, the explanation for the phase transition-preventing layer 35 will be conducted and the explanation for similar components will not be conducted.

As described in the first embodiment, the first crystalline region 121 of the functional substrate 12 has a crystal orientation different from the one of the support substrate 11 and the second crystalline region 122 of the functional substrate 12 has the same crystal orientation as the one of the support substrate 11 originated from the recrystallizing process in the manufacturing method to be described hereinafter. However, since the phase transition-preventing layer 35 is provided, the first crystalline region 121 of the functional substrate 12 is not subject to the crystal orientation of the support substrate 11 in the recrystallizing process so as not to have the same crystal orientation as the one of the support substrate 11 different from the case of the second crystalline region 122 of the functional substrate 12.

As a result, the first crystalline region 121 and the second crystalline region 122 which have the respective different crystal orientations can be efficiently formed on the support substrate 11.

The phase transition-preventing layer 35 may contain at least one selected from the group consisting of carbon, nitrogen and oxygen. Concretely, the phase transition-preventing layer 35 can be formed by ion-implanting the selected element from the group into the support substrate 11.

### (Manufacturing Method of Semiconductor Substrate)

Then, the manufacturing method of the semiconductor substrate as described above will be described.

### FIRST EMBODIMENT

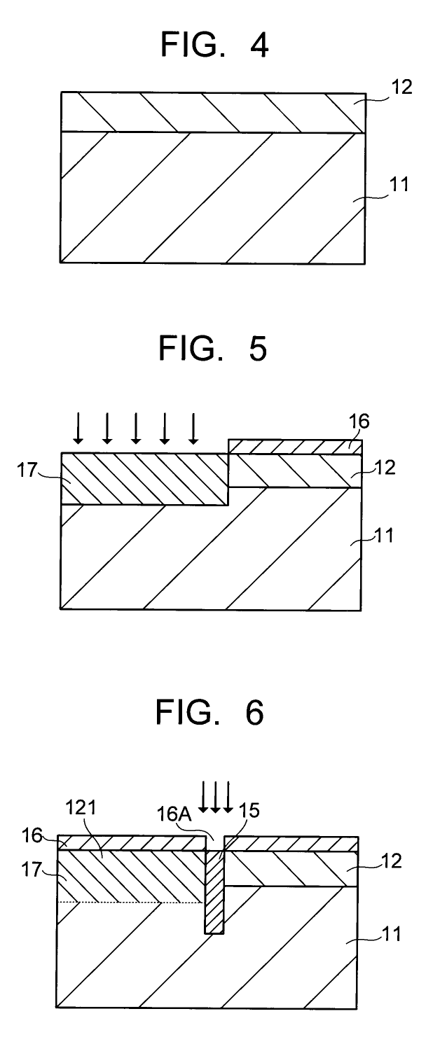

FIGS. 4 to 6 are cross sectional views for explaining the manufacturing method of a semiconductor substrate according to a first embodiment. Like or corresponding components are designated by the same reference numerals through FIGS. 1 and 4 to 6.

First of all, as shown in FIG. 4, the functional substrate 12 made of, e.g., (110) Si substrate is directly bonded with and laminated on the support substrate 11 made of, e.g., (100) Si substrate. Then, as shown in FIG. 5, an insulating film 16 is formed so as to cover almost the right half side of the main surface of the functional substrate 12, for example. The insulating film 16 may be made of a resist film. The functional substrate 12 may be thinned as occasion demands after the lamination.

Then, as shown in FIG. 5, ion implantation of, e.g., germanium is conducted for the resultant laminated body via the insulating film 16 such that the left half side of the functional substrate 12 is rendered amorphous to form an amorphous silicon layer 17. Instead of germanium, silicon may be employed in the ion implantation.

Then, as shown in FIG. 6, the insulating film 16 is additionally formed so as to cover the amorphous silicon layer 17 of the functional substrate 12 and position an opening 16A at the interface between the amorphous silicon layer 17 and the adjacent non-amorphous silicon layer. Then, ion implantation of at least one selected from the group consisting of carbon, nitrogen and oxygen is conducted using the insulating layer 16 as a mask to form an ion implantation layer 15 as an impurity creation-preventing later at the interface therebetween. Thereafter, thermal treatment is conducted for the support substrate 11 and the functional substrate 12 so as to recrystallize the amorphous silicon layer 17. In this case, since the amorphous silicon layer 17 is positioned on the support substrate 11, the amorphous silicon layer 17 is recrystallized so as to inherit the crystal orientation of the support substrate 11.

In the ion implantation, it is desired that the implantation concentration is set to 1.8×10²⁰/cm³ or more.

In FIG. 6, although the ion implantation layer 15 is formed so as to be elongated into the support substrate 11, the ion implantation layer 15 has only to be formed so as to be elongated to the interface between the support substrate 11 and the functional substrate 12.

As a result, as shown in FIG. 1, the functional substrate 12 includes the first crystalline region 121 with the inherent crystal orientation thereof and the second crystalline region 122 which inherits the crystal orientation of the support substrate 11 located via the ion implantation layer 15. Since the crystal orientation of the support substrate 11 is different from the crystal orientation of the functional substrate 12 one another, the crystal orientation of the first crystalline region 121 is also different from the crystal orientation of the second crystalline region 122.

In the recrystallization, since the amorphous silicon layer 17 to be the second crystalline region 122 later is located with separation from the non-amorphous region to be the first crystalline region 121 later via the ion implantation layer 15, the creation of defect around the interface between the first crystalline region 121 and the second crystalline region 122 can be prevented.

Herein, the thermal treatment may be conducted at 1200° C. or more under non-oxidation atmosphere, for example. The thermal treatment period of time may be set in the order of several hours. The remaining insulating film 16 can be removed by means of etching using etching solution or ashing. As a result, the intended semiconductor substrate shown in FIG. 1 can be obtained.

### SECOND EMBODIMENT

FIGS. 4, 7 and 8 are cross sectional views for explaining the manufacturing method of a semiconductor substrate according to a second embodiment. Like or corresponding components are designated by the same reference numerals through FIGS. 1 and 4 to 8.

First of all, as shown in FIG. 4, the functional substrate 12 made of, e.g., (110) Si substrate is directly bonded with and laminated on the support substrate 11 made of, e.g., (100) Si substrate. The functional substrate 12 may be thinned as occasion demands after the lamination.

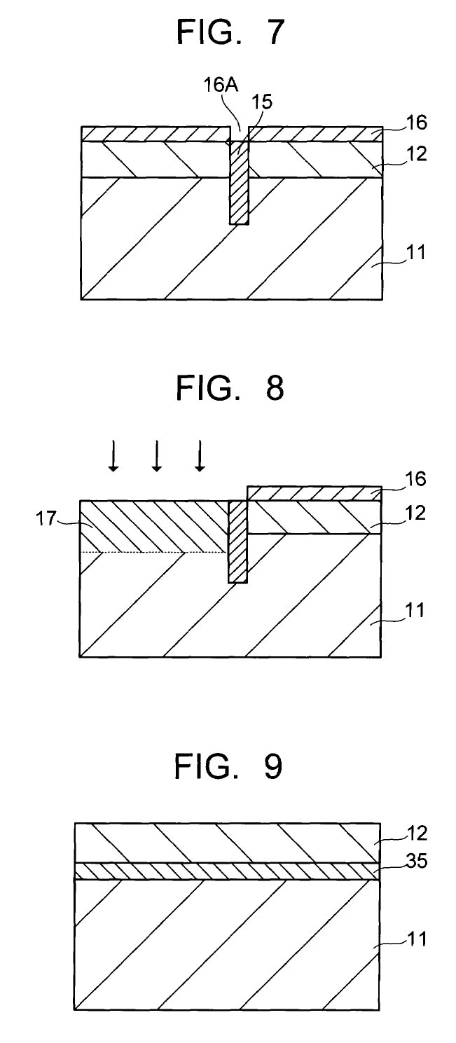

Then, as shown in FIG. 7, an insulating film 16 is formed so that the opening 16A can be formed almost at the center of the main surface of the functional substrate 12. The insulating film 16 may be made of a resist film. Then, ion implantation of, e.g., at least one selected from the group consisting of carbon, nitrogen and oxygen is conducted for the resultant laminated body via the insulating film 16 to form the ion implantation layer 15 as the impurity creation-preventing layer at the opening 16A such that the ion implantation layer 15 can be elongated into the support substrate 11. In FIG. 7, although the ion implantation layer 15 is formed so as to be elongated into the support substrate 11, the ion implantation layer 15 has only to be formed so as to be elongated to the interface between the support substrate 11 and the functional substrate 12.

Then, as shown in FIG. 8, the left half side of the insulating film 16 is removed and ion implantation of, e.g., germanium is conducted for the exposed portion of the functional substrate 12 via the left half side of the insulating film 16 so that the left half side of the functional substrate 12 is rendered amorphous to form an amorphous silicon layer 17. Instead of germanium, silicon may be employed in the ion implantation. Thereafter, thermal treatment is conducted for the support substrate 11 and the functional substrate 12 so as to recrystallize the amorphous silicon layer 17. In this case, since the amorphous silicon layer 17 is positioned on the support substrate 11, the amorphous silicon layer 17 is recrystallized so as to inherit the crystal orientation of the support substrate 11.

As a result, as shown in FIG. 1, the functional substrate 12 includes the first crystalline region 121 with the inherent crystal orientation thereof and the second crystalline region 122 which inherits the crystal orientation of the support substrate 11 located via the ion implantation layer 15. Since the crystal orientation of the support substrate 11 is different from the crystal orientation of the functional substrate 12 one another, the crystal orientation of the first crystalline region 121 is also different from the crystal orientation of the second crystalline region 122.

In the recrystallization, since the amorphous silicon layer 17 to be the second crystalline region 122 later is located with separation from the non-amorphous region to be the first crystalline region 121 later via the ion implantation layer 15, the creation of defect around the interface between the first crystalline region 121 and the second crystalline region 122 can be prevented.

Herein, the thermal treatment, the removal of the insulating layer and the ion implantation can be conducted in the same manner as the first embodiment.

### THIRD EMBODIMENT

FIGS. 9 to 12 are cross sectional views for explaining the manufacturing method of a semiconductor substrate according to a third embodiment. Like or corresponding components are designated by the same reference numerals through FIGS. 1 and 4.

First of all, as shown in FIG. 9, the phase transition-preventing layer 35 is formed on the support substrate 11 made of, e.g., (100) Si substrate, and the functional substrate 12 made of, e.g., (110) Si substrate is bonded with and laminated on the support substrate 11 via the phase transition-preventing layer 35. The phase transition-preventing layer 35 may contain at least one selected from the group consisting of carbon, nitrogen and oxygen. Concretely, ion implantation of the selected element from the group is conducted for the support substrate 11 to form the phase transition-preventing layer 35. The functional substrate 12 may be thinned as occasion demands after the lamination.

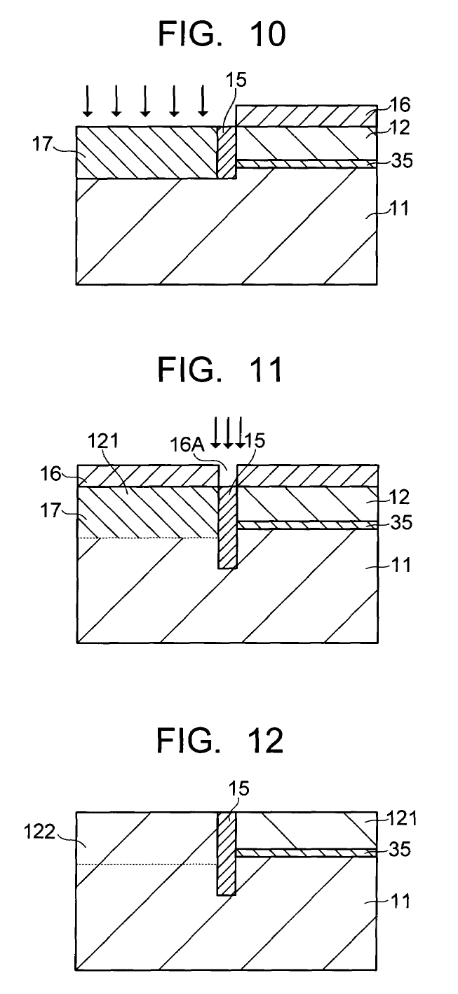

Then, as shown in FIG. 10, an insulating film 16 is formed so as to cover almost the right half side of the main surface of the functional substrate 12. The insulating film 16 may be made of a resist film. Then, ion implantation of, e.g., germanium is conducted for the exposed portion of the functional substrate 12 via the left half side of the insulating film 16 so that the left half side of the functional substrate 12 is rendered amorphous to form an amorphous silicon layer 17. Instead of germanium, silicon may be employed in the ion implantation.

Then, as shown in FIG. 11, the insulating film 16 is additionally formed so as to cover the amorphous silicon layer 17 of the functional substrate 12 and position an opening 16A at the interface between the amorphous silicon layer 17 and the adjacent non-amorphous silicon layer. Then, ion implantation of at least one selected from the group consisting of carbon, nitrogen and oxygen is conducted using the insulating layer 16 as a mask to form an ion implantation layer 15 as an impurity creation-preventing later at the interface therebetween.

Thereafter, as shown in FIG. 12, the insulating film 16 is removed by means of etching using etching solution or ashing and thermal treatment is conducted for the support substrate 11 and the functional substrate 12 so as to recrystallize the amorphous silicon layer 17. In this case, since the amorphous silicon layer 17 is positioned on the support substrate 11, the amorphous silicon layer 17 is recrystallized so as to inherit the crystal orientation of the support substrate 11.

In FIGS. 11 and 12, although the ion implantation layer 15 is formed so as to be elongated into the support substrate 11, the ion implantation layer 15 has only to be formed so as to be elongated to the interface between the support substrate 11 and the functional substrate 12.

As a result, as shown in FIG. 3, the functional substrate 12 includes the first crystalline region 121 with the inherent crystal orientation thereof and the second crystalline region 122 which inherits the crystal orientation of the support substrate 11 located via the ion implantation layer 15. Since the crystal orientation of the support substrate 11 is different from the crystal orientation of the functional substrate 12 one another, the crystal orientation of the first crystalline region 121 is also different from the crystal orientation of the second crystalline region 122.

In the recrystallization, since the amorphous silicon layer 17 to be the second crystalline region 122 later is located with separation from the non-amorphous region to be the first crystalline region 121 later via the ion implantation layer 15, the creation of defect around the interface between the first crystalline region 121 and the second crystalline region 122 can be prevented. Moreover, since the phase transition-preventing layer 35 is provided, the first crystalline region 121 of the functional substrate 12 is not subject to the crystal orientation of the support substrate 11 in the recrystallization so that the crystal orientation of the first crystalline region 121 does not inherit the crystal orientation of the support substrate 11 different from the second crystalline region 122.

Herein, the thermal treatment may be conducted at 1200° C. or more under non-oxidation atmosphere, for example, in the same manner as the first embodiment. The thermal treatment period of time may be set in the order of several hours. The ion implantation can be conducted in the same manner as the first embodiment.

### FOURTH EMBODIMENT

FIGS. 9 and 13 to 14 are cross sectional views for explaining the manufacturing method of a semiconductor substrate according to a fourth embodiment. Like or corresponding components are designated by the same reference numerals through FIGS. 3 and 11 to 12.

First of all, as shown in FIG. 9, the phase transition-preventing layer 35 is formed on the support substrate 11 made of, e.g., (100) Si substrate, and the functional substrate 12 made of, e.g., (110) Si substrate is bonded with and laminated on the support substrate 11 via the phase transition-preventing layer 35. The phase transition-preventing layer 35 may contain at least one selected from the group consisting of carbon, nitrogen and oxygen. Concretely, ion implantation of the selected element from the group is conducted for the support substrate 11 to form the phase transition-preventing layer 35. The functional substrate 12 may be thinned as occasion demands after the lamination.

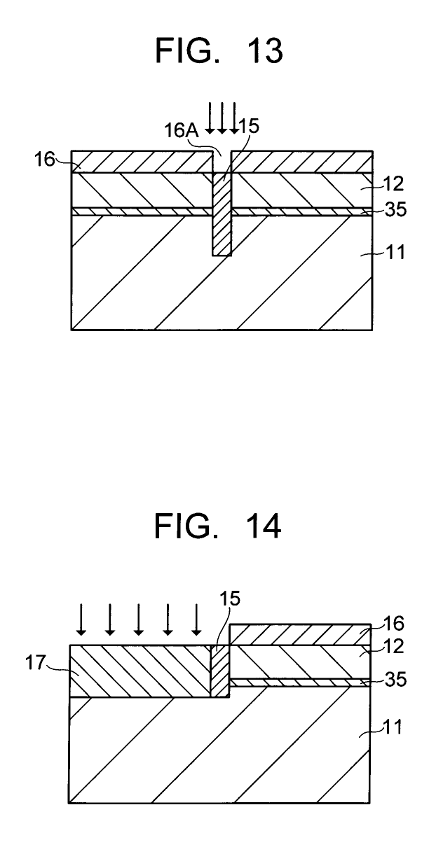

Then, as shown in FIG. 13, an insulating film 16 is formed so that the opening 16A can be formed almost at the center of the main surface of the functional substrate 12. The insulating film 16 may be made of a resist film. Then, ion implantation of, e.g., at least one selected from the group consisting of carbon, nitrogen and oxygen is conducted for the resultant laminated body via the insulating film 16 to form the ion implantation layer 15 as the impurity creation-preventing layer at the opening 16A such that the ion implantation layer 15 can be elongated into the support substrate 11. In FIG. 13, although the ion implantation layer 15 is formed so as to be elongated into the support substrate 11, the ion implantation layer 15 has only to be formed so as to be elongated to the interface between the support substrate 11 and the functional substrate 12.

Then, as shown in FIG. 14 the left half side of the insulating film 16 is removed and ion implantation of, e.g., germanium is conducted for the exposed portion of the functional substrate 12 via the right half side of the insulating film 16 so that the left half side of the functional substrate 12 is rendered amorphous to form an amorphous silicon layer 17. Instead of germanium, silicon may be employed in the ion implantation. After the insulating film 16 is partially removed, thermal treatment is conducted for the support substrate 11 and the functional substrate 12 so as to recrystallize the amorphous silicon layer 17. In this case, since the amorphous silicon layer 17 is positioned on the support substrate 11, the amorphous silicon layer 17 is recrystallized so as to inherit the crystal orientation of the support substrate 11. As a result, result, the semiconductor substrate 30 shown in FIG. 3 can be obtained.

Herein, the thermal treatment may be conducted at 1200° C. or more under non-oxidation atmosphere, for example, in the same manner as the first embodiment. The thermal treatment period of time may be set in the order of several hours. The ion implantation can be conducted in the same manner as the first embodiment.

Although the present invention was described in detail with reference to the above examples, this invention is not limited to the above disclosure and every kind of variation and modification may be made without departing from the scope of the present invention.

What is claimed is:

1. A semiconductor substrate, comprising:
a silicon support substrate with a first crystal orientation;
a silicon functional substrate which is formed on the silicon support substrate and which has a first crystalline region with a crystal orientation different from the first crystal orientation of the silicon support substrate and a second crystalline region with a crystal orientation equal to the first crystal orientation of the silicon support substrate; and
a defect creation-preventing region formed at an interface between the first crystalline region and the second crystalline region of the silicon functional substrate so as to be at least elongated to a main surface of the silicon support substrate.

2. The semiconductor substrate as set forth in claim 1,
wherein the defect creation-preventing region is an ion implantation layer of at least one selected from the group of carbon, nitrogen and oxygen.

3. The semiconductor substrate as set forth in claim 1, further comprising a phase transition-preventing layer formed between the silicon support substrate and the silicon functional substrate.

4. The semiconductor substrate as set forth in claim 3,
wherein the phase transition-preventing layer is formed between the silicon support substrate and the first crystalline region of the silicon functional substrate.

5. The semiconductor substrate as set forth in claim 3,
wherein the phase transition-preventing layer contains at least one selected from the group consisting of carbon, nitrogen and oxygen.

6. A method for manufacturing a semiconductor substrate, comprising:
laminating, on a silicon support substrate with a first crystal orientation, a silicon functional substrate with a second crystal orientation different from the first crystal orientation;
forming an insulating film so as to cover a portion of a main surface of the silicon functional substrate;
conducting first ion implantation for the silicon functional substrate so as to render amorphous a portion not covered with the insulating film of the silicon functional substrate to form an amorphous silicon layer in the silicon functional substrate;
forming an additional insulating film so as to cover the amorphous silicon layer and position an opening at an interface between the amorphous silicon layer and an adjacent non-amorphous silicon layer;
conducting second ion implantation via the opening to form an ion implantation layer as a defect creation-preventing layer so as to be at least elongated to a main surface of the silicon support substrate; and
conducting thermal treatment for the silicon support substrate and the silicon functional substrate to recrystallize the amorphous silicon layer.

7. The method as set forth in claim 6,
wherein the first ion implantation is conducted by ion-implanting germanium or silicon.

8. The method as set forth in claim 6,
wherein the second ion implantation is conducted by ion-implanting at least one of selected from the group consisting of carbon, nitrogen and oxygen.

9. The method as set forth in claim 6,
wherein the thermal treatment is conducted at 1200° C. or more under non-oxidation atmosphere.

10. A method for manufacturing a semiconductor substrate, comprising:
laminating, on a silicon support substrate with a first crystal orientation, a silicon functional substrate with a second crystal orientation different from the first crystal orientation;
forming an insulating film so as to have an opening almost at a center of a main surface of the silicon functional substrate;
conducting first ion implantation via the opening to form an ion implantation layer as a defect creation-preventing layer so as to be at least elongated to a main surface of the silicon support substrate;
removing a portion of the insulating film and conducting second ion implantation for the silicon functional substrate so as to render amorphous a portion not covered with the insulating film of the silicon functional substrate to form an amorphous silicon layer in the silicon functional substrate; and
conducting thermal treatment for the silicon support substrate and the silicon functional substrate to recrystallize the amorphous silicon layer.

11. The method as set forth in claim 10,
wherein the first ion implantation is conducted by ion-implanting at least one of selected from the group consisting of carbon, nitrogen and oxygen.

12. The method as set forth in claim 10,
wherein the second ion implantation is conducted by ion-implanting germanium or silicon.

13. A method for manufacturing a semiconductor substrate, comprising:
forming a phase transition-preventing layer on a silicon support substrate with a first crystal orientation;
laminating, on the silicon support substrate, a silicon functional substrate with a second crystal orientation different from the first crystal orientation via the phase transition-preventing layer;
forming an insulating film so as to cover a portion of a main surface of the silicon functional substrate;
conducting first ion implantation for the silicon functional substrate so as to render amorphous a portion not covered with the insulating film of the silicon functional substrate to form an amorphous silicon layer in the silicon functional substrate;
forming an additional insulating film so as to cover the amorphous silicon layer and position an opening at an interface between the amorphous silicon layer and an adjacent non-amorphous silicon layer;
conducting second ion implantation via the opening to form an ion implantation layer as a defect creation-preventing layer so as to be at least elongated to a main surface of the silicon support substrate; and
conducting thermal treatment for the silicon support substrate and the silicon functional substrate to recrystallize the amorphous silicon layer.

14. The method as set forth in claim 13,
wherein the first ion implantation is conducted by ion-implanting germanium or silicon.

15. The method as set forth in claim 13,
wherein the second ion implantation is conducted by ion-implanting at least one of selected from the group consisting of carbon, nitrogen and oxygen.

16. The method as set forth in claim 13,
wherein the phase transition-preventing layer contains at least one selected from the group consisting of carbon, nitrogen and oxygen.

17. A method for manufacturing a semiconductor substrate, comprising:
forming a phase transition-preventing layer on a silicon support substrate with a first crystal orientation;
laminating, on the silicon support substrate, a silicon functional substrate with a second crystal orientation different from the first crystal orientation;
forming an insulating film so as to form an opening almost at a center of a main surface of the silicon functional substrate;
conducting first ion implantation via the opening to form an ion implantation layer as a defect creation-preventing layer so as to be at least elongated to a main surface of the silicon support substrate;
removing a portion of the insulating film and conducting second ion implantation for the silicon functional substrate so as to render amorphous a portion not covered with the insulating film of the silicon functional substrate to form an amorphous silicon layer in the silicon functional substrate; and
conducting thermal treatment for the silicon support substrate and the silicon functional substrate to recrystallize the amorphous silicon layer.
